(19) United States
(12) Patent Application Publication
(10) Pub. No.: US 2021/0029854 A1
(43) Pub. Date: Jan. 28, 2021

(54) ELECTROMAGNETIC WAVE ABSORBING SHEET AND METHOD FOR PRODUCING SAME

(71) Applicant: DUPONT TEIJIN ADVANCED PAPERS (JAPAN), LTD., Tokyo (JP)

(72) Inventors: Shinji NARUSE, Chiyoda-ku, Tokyo (JP); Tatsushi FUJIMORI, Chiyoda-ku, Tokyo (JP); Koichi UKIGAYA, Chiyoda-ku, Tokyo (JP); Yasunori TANAKA, Chiyoda-ku, Tokyo (JP)

(73) Assignee: DUPONT TEIJIN ADVANCED PAPERS (JAPAN), LTD., Tokyo (JP)

(21) Appl. No.: 17/042,363

(22) PCT Filed: Jan. 29, 2019
(86) PCT No.: PCT/JP2019/002881

§ 371 Date: Sep. 28, 2020

(30) Foreign Application Priority Data
Mar. 30, 2018 (JP) 2018-067164

(51) Int. Cl. H05K 9/00; D21H 27/00; D21H 13/26; D21H 13/50; D21H 21/14

(52) U.S. Cl. CPC H05K 9/009; H05K 9/0094; D21H 21/14; D21H 13/26; D21H 13/50; D21H 27/00

(57) ABSTRACT

The present invention provides an electromagnetic wave absorbing sheet which contains: conductive short fibers; and soft magnetic particles, each of which is covered by an insulating material.

### TECHNICAL FIELD

The present invention relates to an electromagnetic wave absorbing sheet.

### BACKGROUND TECHNOLOGY

With the development of an advanced information society and the advent of a multimedia society, electromagnetic interference, in which electromagnetic waves generated from electronic equipment adversely affect other equipment and the human body, is becoming a major social problem. As the electromagnetic wave environment becomes worse and worse, various electromagnetic wave absorbing sheets have been provided to absorb the electromagnetic waves corresponding to each of these (see Japanese Unexamined Patent Application, Publication No. 2004-140335). For example, for absorption of electromagnetic waves, an electromagnetic wave absorber using ferrite or the like, and an electromagnetic wave absorber using carbon black or the like, have been provided.

However, these electromagnetic wave absorbers absorb electromagnetic waves only in a specific absorption wavelength range, and cannot cope with a wide wavelength range. For example, an electromagnetic wave absorber using ferrite or the like absorbs a band of several GHz, but cannot absorb a band of several tens of GHz. On the other hand, an electromagnetic wave absorber using carbon black or the like can absorb a band of several tens of GHz, but is not suitable for absorption in a band of several GHz. Actually, in order to satisfy conditions such as a desired absorption frequency and a maximum absorption amount at the frequency, a method of appropriately selecting an electromagnetic wave absorber from a plurality of types of radio wave absorbers is used, making practical use of the electromagnetic wave absorber difficult.

Furthermore, high frequency equipment, such as generators, motors, inverters, converters, printed circuit boards, and cables, requiring high efficiency and a large capacity, is becoming small in size and light in weight. Accordingly, there is a demand for an electromagnetic wave absorbing material with high heat resistance which is capable of withstanding the heat generation of a conductive wire caused by the flow of a high frequency current. In particular, in electric and electronic equipment such as inverters and motors, to which a high voltage is to be applied, since the temperature of the equipment rises greatly, a material having high heat resistance is required.

Furthermore, the size and weight of high frequency equipment are being reduced, and in particular, electromagnetic waves radiating with a specific directivity the vicinity of an electromagnetic wave generating source are increasing. Accordingly, there is a demand for an electromagnetic wave absorbing sheet having a small size and a light weight and exhibiting a strong electromagnetic wave absorption property.

### SUMMARY OF INVENTION

An object of the present invention is to provide an electromagnetic wave absorbing sheet capable of absorbing an electromagnetic wave with a wide range and a high frequency, having high heat resistance, and having a light weight.

In order to solve the above-mentioned problems, the present inventors have conducted extensive studies. As a result, they have found that the above-mentioned problems can be solved by an electromagnetic wave absorbing sheet comprising a conductive short fiber and soft magnetic particles covered with an insulating material, and they have completed the present invention.

One embodiment of the present invention is an electromagnetic wave absorbing sheet comprising a conductive short fiber and soft magnetic particles covered with an insulating material. Preferably, the electromagnetic wave absorbing sheet exhibits a particularly large radio wave absorption property in one direction. Further preferably, the electromagnetic wave absorbing sheet has an electromagnetic wave absorption rate of 99% or more in at least one direction of an electromagnetic wave having a frequency range of 6 to 20 GHz. Still further preferably, in the electromagnetic wave absorbing sheet, a change rate in at least one direction of an electromagnetic wave absorption rate at a frequency of 5 GHz after heat treatment at 300° C. for 30 minutes with respect to an electromagnetic wave absorption rate before the heat treatment is preferably 10% or less, and further preferably 1% or less.

A further embodiment is a method for producing an electromagnetic wave absorbing sheet, the method comprising producing a sheet comprising a conductive short fiber and soft magnetic particles covered with an insulating material by a wet papermaking method. Preferably, the method for producing an electromagnetic wave absorbing sheet comprises moving a sheet comprising the conductive short fiber and soft magnetic particles covered with an insulating material to one side and simultaneously reducing the porosity.

A further embodiment is an electric/electronic circuit on which the electromagnetic wave absorbing sheet is mounted.

A further embodiment is a cable on which the electromagnetic wave absorbing sheet is mounted.

Hereinafter, the present invention is described in more detail.

### DESCRIPTION OF EMBODIMENTS

### (Conductive Short Fiber)

Examples of a conductive short fiber to be used in the present invention include a conductive short fiber being a fiber product having a conductivity in a wide range, from a conductor having a volume resistivity of about 10⁻¹ Ω·cm or less to a semiconductor having a volume resistivity of about 10⁻¹ to 10⁸ Ω·cm, and having a relation between the fiber diameter and the fiber length represented by the following formula.

100≤fiber length/fiber diameter≤20000

Examples of such conductive short fiber include, but not limited to, materials having homogeneous conductivity, such as metal fibers, and carbon fibers, and materials obtained by mixing a conductive material and a non-conductive material to exhibit conductivity as a whole, for example, carbon black and materials such as metal plated fibers, metal powder mixed fibers, and carbon black mixed fibers. Among these, in the present invention, it is preferable to use carbon fibers. The carbon fibers used in the present invention are preferably fibers obtained by firing a fibrous organic matter at a high temperature in an inert atmosphere, followed by carbonization. Carbon fibers are generally classified roughly into ones obtained by firing polyacrylonitrile (PAN) fibers and ones obtained by pitch spinning followed by firing. In addition to these, there are also carbon fibers produced by spinning resins such as rayon and phenol, followed by firing, and such fibers can also be used in the present invention. It is also possible to prevent heat cutting at the time of firing by using oxygen and the like to carry out oxidation cross-linking treatment prior to firing.

The fiber length of the conductive short fiber to be used in the present invention is selected from the range of 1 mm to 20 mm.

In the selection of a conductive short fiber, it is more preferable to use materials having a high conductivity and exhibiting good dispersion in the wet paper making method to be described later. Furthermore, when the porosity is reduced along one direction, the conductive short fiber is deformed and cut and thereby an inductor is formed, and an electromagnetic wave absorbing sheet absorbing electromagnetic waves with a wide range and a high frequency can be obtained.

The content of the conductive short fiber in the electromagnetic wave absorbing sheet is preferably 1 wt. % to 40 wt. %, and more preferably 3 wt. % to 20 wt. % with respect to the total weight of the sheet.

### (Insulating Material)

In the present invention, an insulating material is not particularly limited as long as it is a material having a volume resistivity of 1×10⁷ Ω·cm or more, and being capable of covering soft magnetic particles to prevent soft magnetic particles from being brought into contact with each other. It is considered that inorganic matter having high heat resistance is preferable, and in particular, ceramic being excellent also in strength is suitable for covering soft magnetic particles as described in Japanese Unexamined Patent Application, Publication No. 2012-84577.

Furthermore, in order to form a sheet by papermaking as mentioned later, furthermore, as insulating materials for covering, a fibrid of polymetaphenylene isophthalamide (hereinafter, referred to as aramid fibrids) and/or a short fiber of polymetaphenylene isophthalamide (hereinafter, aramid short fiber) is preferably used from the viewpoint that they have characteristics such as good formation processability, flame retardancy, and heat resistance. In particular, fibrids of polymetaphenylene isophthalamide are preferably used from the viewpoint that, due to the form of the film-shaped microparticle, the contact area with the other substance is increased.

Covering of soft magnetic particles with an insulating material may be covering of a part of the soft magnetic particles as long as it can prevent the soft magnetic particles from being brought into contact with each other.

### (Soft Magnetic Particles)

Examples of raw materials of soft magnetic particles to be used in the present invention include at least one metal selected from iron, nickel, and cobalt, or a compound comprising at least one element selected from iron, nickel, and cobalt, having a large relative permittivity when a dispersing body of the metal is formed. Furthermore, the raw material may be an alloy comprising at least one element selected from iron, nickel, and cobalt. Furthermore, the raw material may be crystalline or amorphous. Note here that the soft magnetic body is a magnetic body capable of being magnetized or demagnetized relatively easily. A method for producing the metal soft magnetic body is not particularly limited, and a metal simple substance can be produced by, for example, a reduction method, a carbonyl method, an electrolytic method, and the like, and further alloyed by an appropriate necessary method.

Furthermore, a method for granulating the metal soft magnetic particles is not particularly limited, and examples thereof include a mechanical pulverization method, a bathing powder method, a reduction method, an electrolytic method, a gas phase method, and the like. Furthermore, the shape of powder body may be a spherical shape, a lump shape, a columnar shape, a needle shape, a plate shape, a scale shape, and the like, or shapes may be changed in the post process after granulation.

(Soft Magnetic Particles Covered with Insulating Material)

The soft magnetic particles covered with an insulating material of the present invention are particles in which an insulating property is secured by covering the soft magnetic particles with an insulating material because the soft magnetic particles may be brought into contact with each other. Examples of the covering method include a spraying method, so-called dry covering methods such as CVD and PVD, wet methods of applying and baking sol. Furthermore, particles in which an insulating property is secured can be produced by subjecting composite powder of soft magnetic particles and insulating materials to nitriding treatment, carbonizing treatment, oxidation treatment, and the like. However, the method is not necessarily limited to these methods. Furthermore, in order to additionally strengthen the insulating property, it is preferable to mix an aramid fibrid and/or an aramid short fiber by the below-mentioned papermaking method.

The content of the soft magnetic particles covered with an insulating material in the electromagnetic wave absorbing sheet is preferably 50 wt. % to 90 wt. %, and more preferably 70 wt. % to 80 wt. %, with respect to the total weight of the sheet.

### (Electromagnetic Wave Absorbing Sheet)

The electromagnetic wave absorbing sheet of the present invention can be produced generally by a method of mixing the conductive short fiber and soft magnetic particles covered with an insulating material with each other, followed by being formed into a sheet. Specific examples applicable include, for example, a method of blending a conductive short fiber, soft magnetic particles covered with an insulating material and the aramid fibrid and short fiber mentioned above in a dry method, followed by forming a sheet by use of air stream, and a method of dispersing and mixing a conductive short fiber, soft magnetic particles covered with insulating materials and the aramid fibrid and short fiber mentioned above in a liquid medium, and discharging the mixture onto a liquid permeable support such as a mesh or a belt to form a sheet, followed by removing the liquid for drying. Among these, a so-called wet paper making method using water as a medium is preferable.

A method of kneading conductive short fibers and soft magnetic particles covered with an insulating material with thermoplastic resin and the like by a usual resin kneading method is not preferable because stress is applied to the soft magnetic particles covered with an insulating material, and the insulating material is peeled off from soft magnetic particles, and the soft magnetic particles are brought into contact with each other, so that electromagnetic waves are reflected by each other and are not easily absorbed, or the conductive short fibers are tangled to deteriorate the homogeneous property, causing local unevenness in the electromagnetic wave absorption property.

In the wet paper making method, it is common to feed an aqueous slurry of single one of or a mixture of at least conductive short fiber, soft magnetic particles covered with an insulating material and the aramid fibrid and aramid short fiber described above to a paper making machine for dispersion, followed by dehydration, dewatering, and drying operations to wind it up as a sheet. Examples of the paper making machine usable can include Fourdrinier paper making machines, cylinder paper making machines, inclined paper making machines, and combination paper making machines combining these. In the case of production with a combination paper making machine, it is also possible to obtain a composite sheet composed of several paper layers by sheet-forming and coalescing aqueous slurries having different blending ratios.

Furthermore, in the electromagnetic wave absorbing sheet according to the present invention, the inductors are formed more easily in the case where the conductive short fibers are oriented in one direction with a Fourdrinier paper making machine, a cylinder paper making machine, or an inclined paper making machine when the sheet is moved in one direction, and simultaneously, the porosity is reduced, (described later), and the conductive short fibers are deformed and cut.

Additives such as a dispersibility improver, a defoaming agent, a paper strength enhancer, or the like, may be used if necessary in wet paper making. However, it is necessary to pay attention to their use so as not to hinder the object of the present invention.

Furthermore, the electromagnetic wave absorbing sheet of the present invention may comprise other fibrous components in addition to the above components as long as the object of the present invention is not impaired. For example, organic fibers such as a polyphenylene sulfide fiber, a polyether ether ketone fiber, a cellulose-based fiber, a polyvinyl alcohol fiber, a polyester fiber, a polyarylate fiber, a liquid crystal polyester fiber, a polyimide fiber, a polyamide imide fiber, and a polyparaphenylene benzobisoxazole fiber, inorganic fibers such as a glass fiber, rock wool, and a boron fiber, or the like may be added. Note that the above additives and other fibrous components used are preferably 20 wt. % or less of the total weight of the sheet.

When the thus obtained sheet is subjected to, for example, compression between a pair of rotating metal rolls, the sheet can be moved in one direction and simultaneously made to have a reduced porosity. When the porosity is reduced along one direction, the conductive short fiber is deformed and cut, so that an inductor is formed. Thus, it is possible to obtain an electromagnetic wave absorbing sheet exhibiting a particularly large radio wave absorption property in one direction with a wide range and a high frequency (preferably, an electromagnetic wave absorption rate in at least one direction of an electromagnetic wave having a frequency range of 6 to 20 GHz is 99% or more, and more preferably an electromagnetic wave absorption rate in at least one direction of an electromagnetic wave having a frequency range of 4 to 20 GHz is 90% or more). Furthermore, in the electromagnetic wave absorbing sheet, the change rate in at least one direction of the electromagnetic wave absorption rate at a frequency of 5 GHz at 300° C. for 30 minutes with respect to that before heat treatment is preferably 10% or less, and more preferably 1% or less.

Reduction of the porosity in the present invention means reducing the porosity to ¾ or less of the porosity before reduction of the porosity by, for example, a method of compression between the pair of rotating metal rolls. Specifically, when the porosity before reduction is 80%, the porosity after the reduction is made to be 60% or less, and preferably 55% or less.

In the present invention, the radio wave absorption property that is particularly large in one direction means that a ratio of the absolute value of the minimum value of transmission attenuation rate Rtp in at least one direction of the sheet (mentioned below) to the absolute value of the minimum value of Rtp in a direction orthogonal to the one direction is 1.2 or more. The ratio is preferably 1.5 or more.

Conditions of compression processing for reducing the porosity along one direction are not particularly limited as long as conductive short fibers are deformed and cut along one direction. For example, when compression is carried out between the pair of rotating metal rolls, for example, the surface temperatures of the metal rolls is 100 to 400° C., and the linear pressure between the metal rolls is in a range of 50 to 1000 kg/cm. In order to obtain high tensile strength and surface smoothness, the roll temperature is preferably 270° C. or more, and more preferably 300° C. to 400° C. Furthermore, the linear pressure is preferably 100 to 500 kg/cm. Furthermore, for forming an inductor oriented in one direction, the movement speed of the sheet is preferably 1 m/minute or more, and preferably 2 m/minute or more.

The above-mentioned compression treatment may be carried out at a plurality of times. Compression treatment may be carried out by stacking a plurality of sheet-shaped products obtained by the above-described method.

In addition, the sheets obtained by the above-described method may be stacked or attached to each other using an adhesive or the like to adjust the electromagnetic wave transmission suppression performance and the thickness. For example, in attaching, when the sheets are stacked in a direction orthogonal to the sheet, usually, the direction of the electric field of the electromagnetic waves is orthogonal to the direction of the magnetic field of the electromagnetic waves. Therefore, both the electric field and the magnetic field of the absorbed electromagnetic wave can be arranged in parallel to the inductor. Furthermore, the present invention is an electromagnetic wave absorbing sheet absorbing electromagnetic waves by using both the dielectric loss of the conductive short fiber and the magnetic loss of the soft magnetic particles.

The electromagnetic wave absorbing sheet of the present invention has excellent characteristics such as: (1) having an electromagnetic wave absorption property, (2) exhibiting a radio wave absorption property with a wide range and frequencies including a high frequency by using both the dielectric loss of the conductive short fiber and the magnetic loss of the soft magnetic particles, (3) in particular, an inductor is formed by a conductive short fiber, and soft magnetic particles are positioned inside, thus increasing a large magnetic loss and exhibiting a very large radio wave absorption property, (4) having heat resistance and flame retardancy, and (5) having good processability, and can be suitably used as an electromagnetic wave absorbing sheet of electric and electronic equipment, particularly electronic equipment in hybrid cars and electric automobiles requiring weight reduction. In particular, when the electromagnetic wave absorbing sheet of the present invention is mounted on, for example, electric/electronic circuits such as a printed circuit board, or a cable via the insulating product, the generation of electromagnetic waves is suppressed. Note here that when the electric/electronic circuit is covered with a housing of, for example, metal, and resin, the electromagnetic wave absorbing sheet of the present invention may be fixed to be mounted to the inside with, for example, an adhesive agent, and the like. In this case, an insulated product (air, resin, and the like) is preferably interposed between the electric/electronic circuit and the electromagnetic wave absorbing sheet.

Hereinafter, the present invention is described more specifically with reference to Examples. Note here that these Examples are merely illustrative, and are not intended at all to limit the content of the present invention.

### EXAMPLES

### (Measurement Method)

### (1) Sheet Mark, Thickness, Density, and Porosity

Measurement was carried out in accordance with JIS C 2300-2, and a density was calculated by (mark/thickness). A porosity was calculated from the density, a composition of a raw material, and a specific gravity of the raw material.

### (2) Tensile Strength

The width was 15 mm, the chuck interval was 50 mm, and the tensile rate was 50 mm/min.

### (3) Electromagnetic Wave Absorption Performance

Using a near-field electromagnetic wave evaluation system in accordance with IEC 62333, a sample sheet was laminated on a microstripline (MSL) with a polyethylene film (thickness: 38 μm) sandwiched, 500 g of load was applied to the sheet with an insulating weight, and electric power of the reflected wave S11 and electric power of the transmitted wave S21 for the incident wave of 50 MHz to 20 GHz were measured using a network analyzer.

From the following formula, the transmission attenuation rate Rtp was obtained.

Rtp=10×log[10^{S21/10}(1−10^{S11/10})] (dB)

[10^{S21/10}/(1−10^{S11/10})] represents an electromagnetic wave attenuation rate; and
1−[10^{S21/10}/(1−10^{S11/10})] represents an electromagnetic wave absorption rate.
When Rtp=−20 (dB) is satisfied, the electromagnetic wave absorption rate is 99%.
When Rtp<−20 (dB) is satisfied, the electromagnetic wave absorption rate is more than 99%.

It can be said that the smaller Rtp is, the larger the attenuation of electromagnetic wave is and the higher the electromagnetic wave absorption performance is.

Furthermore, after the sample sheet was heat-treated at 300° C. for 30 minutes, the change rate Cr of the electromagnetic wave absorption rate at a frequency of 5 GHz was obtained from the following formula.

Cr=((electromagnetic wave absorption rate after heat treatment−electromagnetic wave absorption rate before heat treatment)/electromagnetic wave absorption rate before heat treatment

It can be said that the smaller the Cr is, the higher the heat resistance is.

### (Preparation of Raw Material)

A fibrid of polymetaphenylene isophthalamide (hereinafter referred to as the “meta-aramid fibrid”) was produced using the pulp particle production apparatus (wet type precipitator) formed by a combination of a stator and a rotor described in Japanese Patent Application Publication No. Sho 52-15621. This was treated with a beating machine to adjust the length weighted average fiber length to 0.9 mm (freeness: 200 cm³). On the other hand, as a short fiber of polymetaphenylene isophthalamide, a meta-aramid fiber manufactured by Du Pont (Nomex (registered trademark), single thread fineness: 2.2 dtex) was cut to 6 mm in length (hereinafter referred to as the “meta-aramid short fiber”). As the soft magnetic particles covered with an insulating material, iron particles (having an average particle diameter of about 20 μm and comprising a nitride layer as the intermediate layer) covered with silica (having a volume resistivity of 1×10¹⁶ Ω·cm) described in Japanese Patent Application Publication No. 2012-84577 (hereinafter, referred to as the “covered particle”) was prepared as a raw material for paper making.

### Examples 1 and 2

### (Production of Sheet)

Each the meta-aramid fibrid (having a volume resistivity of 1×10¹⁶ Ω·cm), the meta-aramid short fiber (having a volume resistivity of 1×10¹⁶ Ω·cm), and the covered particle, prepared as described above, and carbon fiber (manufactured by Toho Tenax Co., Ltd., and having a fiber length of 3 mm, a single fiber diameter of 7 μm, a fineness of 0.67 dtex, and a volume resistivity of 1.6×10⁻³ Ω·cm) were dispersed in water to produce slurries. These slurries were mixed such that the blend ratios of the meta-aramid fibrid, the meta-aramid short fiber, the covered particle, and the carbon fiber were those shown in Table 1, and were treated using a Tappi type hand paper making machine (having a cross sectional area of 325 cm²) to produce sheet-shaped products (porosity of 83%). Next, the obtained sheets were subjected to compression pressing with a pair of metal calendar rolls under the conditions shown in Table 1 to obtain sheet-shaped products. A plane direction parallel to the rotating direction of the calendar rolls is defined as a longitudinal direction, and a plane direction perpendicular to the longitudinal direction is a transverse direction.

Table 1 shows the main characteristic values of the sheets obtained in this way.

(The specific gravity of the raw material was 1.38 for the meta-aramid fibrid, 1.38 for the meta-aramid short fiber, 6.1 for the covered particles, and 1.8 for the carbon fiber.)

TABLE 1

| Characteristics | Unit | Example 1 | Example 2 |
|---|---|---|---|
| Raw material composition | wt. % | | |
| Meta-aramid fibrid | | 15 | 50 |
| Meta-aramid short fiber | | 5 | 0 |
| Covered particles | | 75 | 75 |
| Carbon fiber | | 5 | 10 |
| Compression conditions | | | |
| Roll temperature | ° C. | 300 | 300 |
| Linear pressure | kgf/cm | 200 | 200 |
| Speed | m/min | 2 | 2 |
| Basic weight | g/m² | 190 | 183 |
| Thickness | μm | 98 | 100 |
| Density | g/cm³ | 1.94 | 1.83 |
| Porosity | % | 42 | 48 |
| Longitudinal tensile | kgf/15 mm | 5.6 | 4.1 |
| strength | | | |
| MSL is in parallel to | | | |
| longitudinal direction | | | |
| Frequency at Rtp < −20 dB | GHz | 5.8 to 20 | 4.1 to 20 |
| Rtp minimum value | dB | −58 | −87 |
| Frequency at the time | GHz | 16.1 | 10.3 |
| Cr at frequency of 5 GHz | % | 0.01 | 0.07 |
| before and after heat | | | |
| treatment at 300° C. for 30 | | | |
| min | | | |
| MSL is in parallel to | | | |
| traverse direction | | | |
| Frequency at Rtp < −20 dB | GHz | 6.0 to 20 | 12.3 to 19 |
| Rtp minimum value | dB | −48 | −22 |
| Frequency at the time | GHz | 13.5 | 15.2 |
| Cr at frequency of 5 GHz | % | 0.004 | 0.06 |
| before and after heat | | | |
| treatment at 300° C. for 30 | | | |
| min | | | |
| Ratio of absolute value of | | 1.21 | 3.95 |
| Rtp minimum value | | | |

### Comparative Example

### (Production of Sheet)

Each the meta-aramid fibrid, the meta-aramid short fiber, and the covered particles, prepared as described above, were dispersed in water to prepare a slurry. This slurry was mixed such that the blend ratios of the meta-aramid fibrid, the meta-aramid short fiber, and the covered particles were those as shown in Table 2, and treated with a Tappi type hand paper making machine (cross sectional area: 325 cm²) to produce a sheet-shaped product. Next, the obtained sheet was subjected to compression pressing with a pair of metal calendar rolls under the conditions shown in Table 2 to obtain a sheet-shaped product. A plane direction parallel to the rotating direction of the calendar rolls is defined as a longitudinal direction, and a plane direction perpendicular to the longitudinal direction is defined as a transverse direction.

Table 2 shows the main characteristic values of the sheet obtained in this way.

TABLE 2

| | | Comparative |
|---|---|---|
| Characteristics | Unit | Example |
| Raw material composition | wt. % | |
| Meta-aramid fibrid | | 15 |
| Meta-aramid short fiber | | 10 |
| Covered particles | | 75 |
| Carbon fiber | | 0 |
| Compression conditions | | |
| Roll temperature | ° C. | 300 |
| Linear pressure | kgf/cm | 200 |
| Speed | m/min | 2 |
| Basic weight | g/m² | 199 |
| Thickness | μm | 100 |
| Density | g/cm³ | 1.99 |
| Porosity | % | 40 |
| Longitudinal tensile strength | kgf/15 mm | 7.1 |
| MSL is in parallel to | | |
| longitudinal direction | | |
| Frequency at Rtp < −20 dB | GHz | None |
| Rtp minimum value | dB | −5.5 |
| Frequency at the time | GHz | 18.4 |
| Cr at frequency of 5 GHz before | % | 21.0 |
| and after heat treatment at | | |
| 300° C. for 30 min | | |
| MSL is in parallel to traverse | | |
| direction | | |
| Frequency at Rtp < −20 dB | GHz | None |
| Rtp minimum value | dB | −4.9 |
| Frequency at the time | GHz | 18.4 |
| Cr at frequency of 5 GHz before | % | 20.4 |
| and after heat treatment at | | |
| 300° C. for 30 min | | |
| Ratio of absolute value of Rtp | | 1.12 |
| minimum value | | |

As shown in Table 1, the electromagnetic wave absorbing sheets of Examples 1 and 2 exhibited excellent characteristics for an electromagnetic wave absorption property with a wide range and frequencies including a high frequency to 20 GHz. In particular, the electromagnetic wave absorbing sheet shown in Example 2 exhibited excellent characteristics in at least one direction.

On the contrary, as shown in Table 2, the sheet of Comparative Example had a narrow frequency range exhibiting an electromagnetic wave absorption property, and was not sufficient as the objective electromagnetic wave absorbing sheet.

1. An electromagnetic wave absorbing sheet comprising a conductive short fiber and soft magnetic particles covered with an insulating material.

2. The electromagnetic wave absorbing sheet according to claim 1, exhibiting a particularly large radio wave absorption property in one direction.

3. The electromagnetic wave absorbing sheet according to claim 1, wherein an electromagnetic wave absorption rate in at least one direction of an electromagnetic wave having a frequency range of 6 to 20 GHz is 99% or more.

4. The electromagnetic wave absorbing sheet according to claim 1, wherein a change rate in at least one direction of an electromagnetic wave absorption rate at a frequency of 5 GHz after heat treatment at 300° C. for 30 minutes with respect to an electromagnetic wave absorption rate before the heat treatment is 10% or less.

5. The electromagnetic wave absorbing sheet according to claim 1, wherein a change rate in at least one direction of an electromagnetic wave absorption rate at a frequency of 5 GHz after heat treatment at 300° C. for 30 minutes with respect to an electromagnetic wave absorption rate before the heat treatment is 1% or less.

6. A method for producing the electromagnetic wave absorbing sheet according to claim 1, the method comprising producing a sheet comprising a conductive short fiber and soft magnetic particles covered with an insulating material by a wet papermaking method.

7. The method for producing an electromagnetic wave absorbing sheet according to claim 6, comprising moving the sheet comprising the conductive short fiber and soft magnetic particles covered with an insulating material to one side and simultaneously reducing the porosity.

8. An electric and electronic circuit comprising the electromagnetic wave absorbing sheet according to claim 1.

9. A cable comprising the electromagnetic wave absorbing sheet according to claim 1.
